(19) United States
(12) Patent Application Publication
(10) Pub. No.: US 2026/0173953 A1
(43) Pub. Date: Jun. 18, 2026

(54) MULTIDIE AND WAFER SEMICONDUCTOR STRUCTURES

(71) Applicant: International Business Machines Corporation, Armonk, NY (US)

(72) Inventors: Nicholas Alexander POLOMOFF, Hopewell Junction, NY (US); RAVI K. BONAM, Albany, NY (US); Eric Perfecto, Poughkeepsie, NY (US); Roy R. Yu, Poughkeepsie, NY (US); Katsuyuki Sakuma, Fishkill, NY (US)

(21) Appl. No.: 18/981,332

(22) Filed: Dec. 13, 2024

(51) Int. Cl. H01L 23/29; H01L 23/00; H01L 23/538

(52) U.S. Cl. CPC H10W 74/43; H10W 70/611; H10W 70/635; H10W 70/65; H10W 72/90; H10W 72/926; H10W 72/944

(57) ABSTRACT

A semiconductor structure includes a semiconductor wafer having an insulating surface and a plurality of metal pads thereon; and a plurality of individual semiconductor dies having a front side and a back side. Each die has an insulating surface and metal pads on the front side. The plurality of individual semiconductor dies are positioned over and hybrid bonded to the semiconductor wafer and respective metal pads and insulating surfaces of the semiconductor wafer and the plurality of semiconductor dies are aligned and hybrid bonded face to face. An encapsulating material is positioned over the semiconductor wafer and the plurality of semiconductor dies to provide mechanical stability and an insulating surface over the plurality of individual semiconductor dies.

### BACKGROUND

The present invention relates to the electrical, electronic, and computer arts, and more specifically, to semiconductor structures having die-to-wafer builds, reconstituted wafer builds, and wafer-to-wafer builds for further assembly or packaging.

There is a need to place more memory and logic into current integrated circuit packages, which have a limited number of pins or connections. One way to do this is to place more circuitry or transistors on a die or chip of a given size and then to put more dies or chips into an integrated circuit (IC) package. Dies or chips can be preassembled on a wafer, can be stacked, and can be thinned to reduce the volume as ways to increase the interconnection density and to put more memory and logic in an integrated circuit package.

### SUMMARY

Principles of the invention provide techniques for building multi-die semiconductor structures. In one aspect, an exemplary semiconductor structure includes a semiconductor wafer having an insulating surface and metal pads thereon; and a plurality of semiconductor dies having a front side and a back side, each die having an insulating surface and metal pads on the front side. The plurality of semiconductor dies are positioned over the semiconductor wafer. Respective metal pads and insulating surfaces of the semiconductor wafer and the plurality of semiconductor dies are aligned and hybrid bonded face-to-face, and an encapsulating material is positioned over the semiconductor wafer and the plurality of semiconductor dies to provide mechanical stability and an insulating surface over the plurality of individual semiconductor dies.

In another aspect, an exemplary semiconductor build includes first and second semiconductor structures. Each of the first and second semiconductor structures includes a semiconductor wafer having a dielectric surface and metal pads thereon; and a plurality of semiconductor dies having a front side and a back side, each die having a dielectric surface and metal pads on a front side. The plurality of individual semiconductor dies are positioned over and hybrid bonded to the semiconductor wafer. Respective metal pads and insulating surfaces of the semiconductor wafer and the plurality of dies are aligned and hybrid bonded face to face. An encapsulating material is positioned over the semiconductor wafer and the plurality of semiconductor dies to provide mechanical stability and an insulating surface over the plurality of individual semiconductor dies. The overmold insulating surface has metal pads suitable for hybrid bonding. The second semiconductor structure is positioned over the first semiconductor structure and the metal pads on the overmold insulating surface of the second semiconductor structure are aligned and hybrid bonded to the metal pads on the overmold insulating surface of the first semiconductor structure.

In still another aspect, an exemplary multi-die semiconductor structure includes a first die having a semiconductor substrate, semiconductor devices, and a back end of the line (BEOL) wiring layer connected to the devices and to metal pads suitable for hybrid bonding on a first major surface of the first die. Also included are a second and third die each having a semiconductor substrate, semiconductor devices, a BEOL wiring layer connected to the devices and to metal pads suitable for hybrid bonding on a first major surface of the second and third die. Each of the second and third dies further include a plurality of through silicon vias (TSVs) extending from the BEOL wiring layer through the semiconductor substrates to a backside of the second and third die. The metal pads on the first major surface of the second and third die are hybrid bonded to the metal pads on the first major surface of the first die. An encapsulating material is positioned over the first, second and third dies to provide added mechanical stability to the first, second and third dies. A patterned redistribution layer on the encapsulating material and on the backside of the second and third die is provided for forming interconnections to the TSVs, and the TSVs are coupled to metal pads formed on the patterned redistribution layer.

Techniques as disclosed herein can provide substantial beneficial technical effects. Some embodiments may not have these potential advantages and these potential advantages are not necessarily required of all embodiments. By way of example only and without limitation, one or more embodiments may provide:
face to face die to wafer hybrid bonding,
reconstituted wafer builds,
wafer to wafer hybrid bonding,
additional wiring levels,
wafer fan out wiring,
more die layers with less hybrid bonding steps,
no need to planarize down to the backside of thinned die,
testing at multiple levels and or process steps,
no need of an additional silicon support carrier,
no need for through silicon vias (TSVs) in certain dies,
no need for very thick oxide on individual builds,
very short interconnection lengths,
high density multidie structures,
three-dimensional (3D) multidie structures,
parallel multidie stacked structures, and
mechanically robust structures.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1A-1E depict a process flow illustration for building a first embodiment of the invention.

FIGS. 2A-2D depict a process flow illustration for building a second embodiment of the invention.

FIG. 3 is a cross-sectional view of a third embodiment of the invention.

FIG. 4 is a cross-sectional view of a fourth embodiment of the invention.

FIG. 5 is a cross-sectional view of a fifth embodiment of the invention.

FIG. 6 provides an enlarged, inverted view of a portion of the embodiments of FIG. 5.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Aspects of the invention relate to a multidie and wafer semiconductor structures. One or more embodiments advantageously provide for reconstructing or reconstituting a semiconductor wafer by assembling selected die(s) and aligning and hybrid bonding the selected die(s) to an underlying wafer and covering the hybrid bonded die(s) by applying an insulating material to encapsulate and form an insulating surface above the die.

Another embodiment advantageously provides for semiconductor dies with face-to-face hybrid bonding, wherein certain die(s) also have multiple through silicon vias (TSVs) to its/their backside surface to metal pads to couple signals and power to another die, wafer, or redistribution layer for further interconnections.

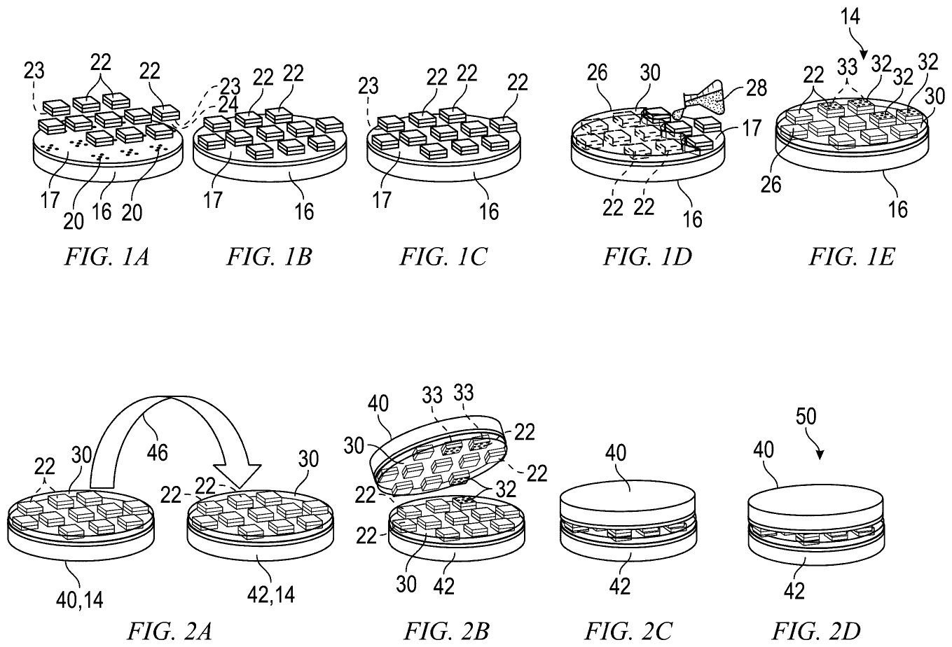

Referring now to the drawings, FIGS. 1A-1E show a process flow illustration for building a reconstituted wafer 14 shown in FIG. 1E. FIG. 1A shows a semiconductor wafer 16 having an insulated surface 17 and a plurality of metal pads 20 thereon suitable for hybrid bonding. Wafer 16 can also be a die large enough in surface area to receive all of the assembled die(s). A plurality of individual semiconductor dies 22 are shown aligned and positioned face down above metal pads 20. Each die 22 has an insulating surface 23 and metal pads 24 thereon facing and aligned above metal pads 20. Metal pads 24 are suitable for hybrid bonding. The plurality of individual semiconductor dies 22 are positioned in contact on wafer 16 as shown in FIG. 1B. In FIG. 1C, wafer 16 and dies 22 are hybrid bonded to semiconductor wafer 16 with a heat treatment anneal. The respective metal pads 24 of dies 22 and metal pads 20 of semiconductor wafer 16 are hybrid bonded face to face and insulating surface 17 of semiconductor wafer 16 and insulating surfaces 23 of individual semiconductor dies 22 are bonded together. Generally, an encapsulating material can include an overmold, an oxide such as a “thick” oxide, and the like.

Next, as shown in FIG. 1D, a thick overmold or oxide film 26 of insulating material 28 is applied and encased on the hybrid bonded dies 22 to semiconductor wafer 16 to provide mechanical stability and to provide an insulating surface 30 over semiconductor wafer 16 and the plurality of individual semiconductor dies 22. Reconstituted wafer 14 shown in FIG. 1E includes wafer 16, thick overmold 26, and the plurality of semiconductor dies 22 that are hybrid bonded to wafer 16.

Insulating surface 30 can have metal pads 32 coupled by way of metal vias to metal pads 33 on the backside of semiconductor dies 22. Semiconductor dies 22 can have through silicon vias (TVSs) (not shown) to couple power and signals from the front side of dies 22 to metal pads 33. Additional wiring levels (not shown), such as a redistribution layer, can be formed on surface 30 coupled to metal pads 32.

Note that, for illustrative clarity, in FIGS. 1E, 2A, 2B, 2C and 2D, while the dies 22 are below insulating surface 30, they are not shown dashed (they are depicted as dashed in FIG. 1D).

FIGS. 2A-2D show a process flow illustration for building a reconstituted wafer to reconstituted wafer (W2W) structure utilizing reconstituted wafers 14 shown in FIG. 1E. In FIG. 2A, reconstituted wafers 14 are shown as reconstituted wafers 40 and 42. Dies 22 of wafers 40 and 42 each have metal pads 33 coupled to metal pads 32 (see FIG. 2B) on insulating surface 30 suitable for hybrid bonding. Wafers 40 and 42 are brought together as shown by arrow 46. Reconstituted wafers 40 and 42 are positioned with respective insulating surfaces 30 facing one another and metal pads 32 on wafer 40 aligned with respect to metal pads 32 on wafer 42, as shown in FIG. 2B. Reconstituted wafers 40 and 42 are hybrid bonded with a heat treatment anneal shown in FIG. 2C to form a reconstituted wafer to reconstitute wafer structure 50 shown in FIG. 2D.

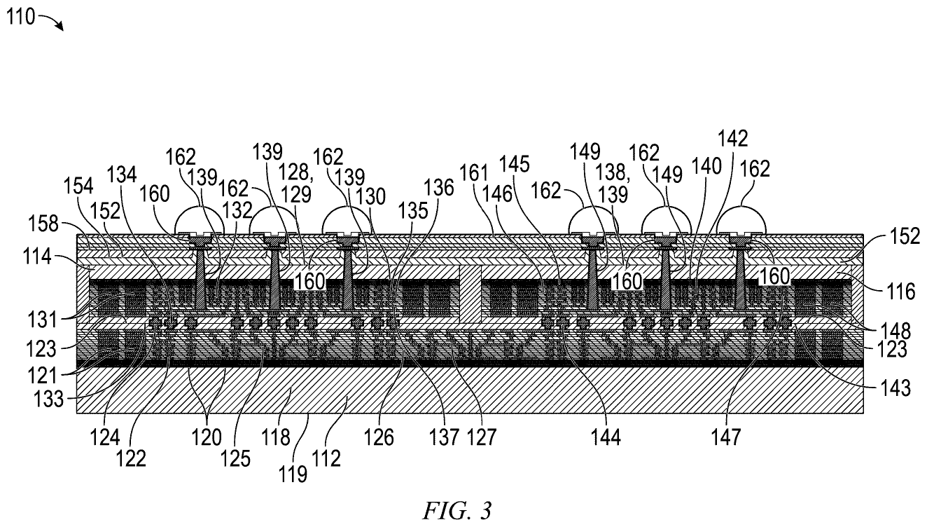

FIG. 3 shows a cross-sectional view of a multidie semiconductor structure 110 having a first die 112, a second die 114, and a third die 116. First die 112 has a semiconductor substrate 118, semiconductor devices 120 formed in semiconductor substrate 118, a back end of the line (BEOL) wiring layer 122 connected to semiconductor devices 120 formed in semiconductor substrate 118 and metal pads 124 on insulating surface 123 coupled to BEOL wiring layer 122. BEOL wiring layer 122 has a plurality of metal interconnect layers 125 spaced apart by respective insulation layers 126 and interconnected between metal layers by metal vias 127. First die 112 has crack stop structures 121 to prevent cracks from propagating into semiconductor substrate 118 and BEOL wiring layer 122. Semiconductor substrate 118 has a backside 119 which is also the backside of first die 112.

Second die 114 has a semiconductor substrate 128, semiconductor devices 130, a back end of the line (BEOL) wiring layer 132 connected to semiconductor devices 130 formed in semiconductor substrate 128 and metal pads 134 on insulating surface 133 coupled to BEOL wiring layer 132. BEOL wiring layer 132 has a plurality of metal interconnect layers 135 spaced apart by respective insulation layers 136 and interconnected between metal layers by metal vias 137. Second die 114 has crack stop structures 131 to prevent cracks from propagating into semiconductor substrate 128 and BEOL wiring layer 132. Second die 114 further includes a plurality of through silicon vias (TSVs) 139 extending from BEOL wiring layer 132 through semiconductor substrate 128 to backside 129 of semiconductor substrate 128.

Third die 116 has a semiconductor substrate 138, semiconductor devices 140, a back end of the line BEOL wiring layer 142 connected to semiconductor devices 140 formed in semiconductor substrate 138 and metal pads 144 on insulating surface 143 coupled to BEOL wiring layer 142. BEOL wiring layer 142 has a plurality of metal interconnect layers 145 spaced apart by respective insulation layers 146 and interconnected between metal layers by metal vias 147. Third die 116 has crack stop structures 148 to prevent cracks from propagating into semiconductor substrate 138 and BEOL wiring layer 142. Third die 116 further includes a plurality of through silicon vias (TSVs) 149 extending from BEOL wiring layer 142 through semiconductor substrate 138 to backside 139 of semiconductor substrate 138.

In FIG. 3, die 114 is aligned with die 112 with respective insulating surfaces 123 and 133 facing each other and wherein insulating surfaces 123 and 133 have been previously planarized. Die 114 and die 112 are then brought together with heat and pressure and are hybrid bonded together with insulating surface 133 bonded to insulating surface 123 and metal pads 124 bonded to metal pads 134. Likewise, die 116 is aligned with die 112 with respective insulating surfaces 123 and 143 facing each other and wherein insulating surfaces 123 and 143 have been previously planarized. Dies 116 and 112 are then brought together with heat and pressure and are hybrid bonded together with insulating surface 143 bonded to insulating surface 123 and metal pads 124 bonded to metal pads 144. Dies 116 and 112 can be hybrid bonded at times when dies 114 and 112 are hybrid bonded or dies 114 and 112 can be hybrid bonded at overlapping or at separate times.

In hybrid bonding, a permanent bond combines a dielectric bond (e.g., SiOx) with embedded metal (e.g., Cu) to form interconnections. Two dies, interconnect structures or semiconductor builds are joined together (e.g., two dies, semiconductor builds, or individual wafers that are built separately). They typically require a “pristine” surface (smooth and flat, possibly with some recesses), more so than traditional chemical-mechanical planarization (CMP). The two semiconductor builds are purposely designed to align. The term “hybrid” refers to the presence of both copper and dielectric. A bond that uses dielectric alone is referred to as fusion bonding (oxide to oxide). Hybrid bonding uses metal to metal connections for the copper. Two dies, 112 and 114 and/or 112 and 116, are brought together facing each other and a small heat treatment/annealing process is carried out. The oxides bond together and the metals “anneal,” or almost melt, together, thus fusing the interface into a single bonded part (in some instances, seamlessly; i.e., the interface line disappears).

Encapsulating material 152 is positioned over multidie semiconductor structure 110 and specifically over die 112 where accessible and over dies 114 and 116 and between dies 114 and 116 which can, for example, be thin (e.g., in the range from 10-50 micrometers) to provide added mechanical stability to multidie semiconductor structure 110. Encapsulating material 152 can be a thick oxide such as chemical vapor deposited (CVD) tetraethylorthosilicate (TEOS). Encapsulating material 152 can be polished by chemical mechanical polishing (CMP) to provide a flat insulating surface 154.

A patterned metal redistribution layer 158 is formed over encapsulating material 152 on surface 154 to form interconnections to TSVs 139 and 149, which are coupled to BEOL wiring layers 132 and 142 of respective dies 114 and 116. Patterned metal redistribution layer 158 can couple TSVs 139 and 149 to metal pads 160 on insulating surface 161 and can couple other metal leads in the patterned metal redistribution layer 158 to metal pads 160. Solder bumps 162 may be formed on metal pads 160 for subsequent interconnection, for example, to an interposer (not shown).

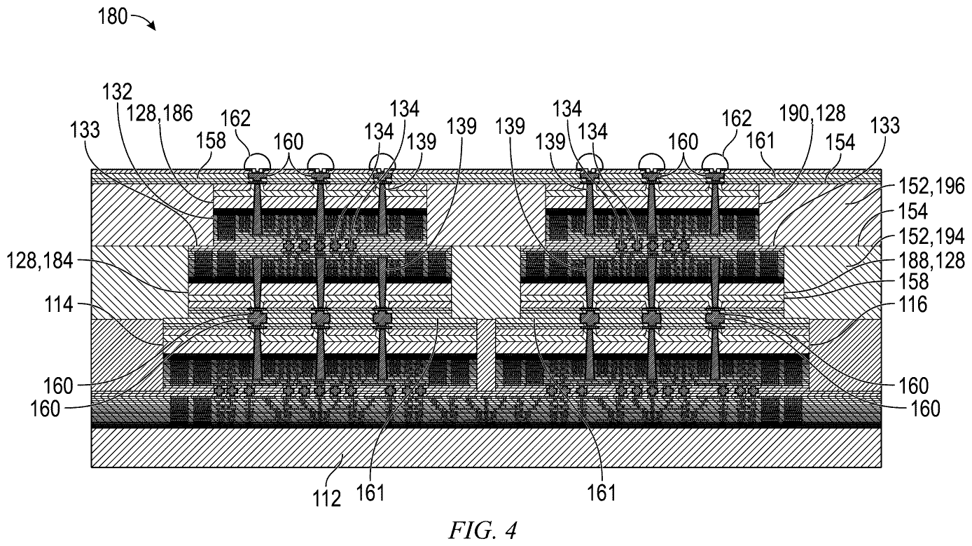

FIG. 4 is a cross-sectional view of semiconductor structure 180 having dies 112, 114 and 116 assembled and interconnected as shown in FIG. 3, except that solder bumps 162 are not applied or formed on dies 114 and 116, so as to leave metal pads 160 on dies 114 and 116 suitable for hybrid bonding.

Die 184 is positioned above die 114 and die 188 is positioned above die 116. Die 186 is positioned above die 184 and die 190 is positioned above die 188. Dies 184, 186, 188 and 190 can, for example, be built with the same internal components as die 114 and can, for example, have different widths, lengths and depths.

Dies 184, 186, 188 and 190 each can have a semiconductor substrate 128, semiconductor devices, a BEOL wiring layer 132 connected to the devices and to metal pads 134 suitable for hybrid bonding on a first major surface 133. Dies 184, 186, 188, and 190 include a plurality of through silicon vias (TSVs) 139 extending from its respective BEOL wiring layer 132 through its semiconductor substrate 128 and a patterned redistribution layer 158 on the backside of dies 186 and 190 to metal pads 160 for forming interconnections.

In FIG. 4, die 184 is aligned with die 114 with respective insulating surfaces 161 facing each other and wherein insulating surfaces 161 have been previously planarized. Metal pads 160 of die 184 are aligned with metal pads 160 of die 114. Die 184 and die 114 are then brought together with heat and pressure and are hybrid bonded together with insulating surfaces 161 bonded together and metal pads 160 bonded together. Likewise, die 188 is aligned with die 116 with respective insulating surfaces 161 facing each other and wherein insulating surfaces 161 have been previously planarized. Metal pads 160 of die 188 are aligned with metal pads 160 of die 116. Dies 188 and 116 are then brought together with heat and pressure and are hybrid bonded together with insulating surfaces 161 bonded together and metal pads 160 bonded together.

In FIG. 4, die 186 is aligned with die 184 with respective insulating surfaces 133 facing each other and wherein surfaces 133 have been previously planarized. Die 186 and die 184 are then brought together with heat and pressure and are hybrid bonded together with insulating surfaces 133 bonded together and metal pads 134 bonded together. Likewise, die 190 is aligned with die 188 with respective insulating surfaces 133 facing each other and wherein surfaces 133 have been previously planarized. Dies 190 and 188 are then brought together with heat and pressure and are hybrid bonded together with insulating surfaces 133 are bonded together and metal pads 134 are bonded together.

Encapsulating material 152 is positioned as a layer 194 around dies 184 and 188 and between dies 184 and 188 which can, for example, be thin (e.g., less than 60 micrometers) to provide added mechanical stability and varying the compressive and tensile stress as a function of depth of encapsulating material 152 to mitigate, manage, and compensate for stress/bow to prevent warping of multidie semiconductor structure 180. Encapsulating material 152 is positioned as a layer 196 over layer 194 and around dies 186 and 190 and between dies 186 and 190 which can, for example, be thin (e.g., such as 10-50 micrometers or less) to provide added mechanical stability and varying the compressive and tensile stress to mitigate, manage and compensate for stress/bow to prevent warping of multidie semiconductor structure 180. Encapsulating material 152 can be, for example, a thick oxide such as chemical vapor deposited (CVD) tetraethylorthosilicate (TEOS). Encapsulating material 152 can be polished by chemical mechanical polishing (CMP) to provide a flat insulating surface 154. The “thick” oxide can correspond in thickness to the “thinned” wafer; e.g., from 10-50 μm; more generally, the oxide can have a thickness of at least 10 μm.

A patterned metal redistribution layer 158 is formed over encapsulating material 152 on surface 154 to form interconnections to TSVs 139 which are coupled to BEOL wiring layer 132 of respective dies 186 and 190. Patterned metal redistribution layer 158 can couple TSVs 139 to metal pads 160 on insulating surface 161 and can couple other metal leads (not shown) in the patterned metal redistribution layer 158 to metal pads 160. Solder bumps 162 can be formed on metal pads 160 for subsequent interconnection, for example, to an interposer (not shown).

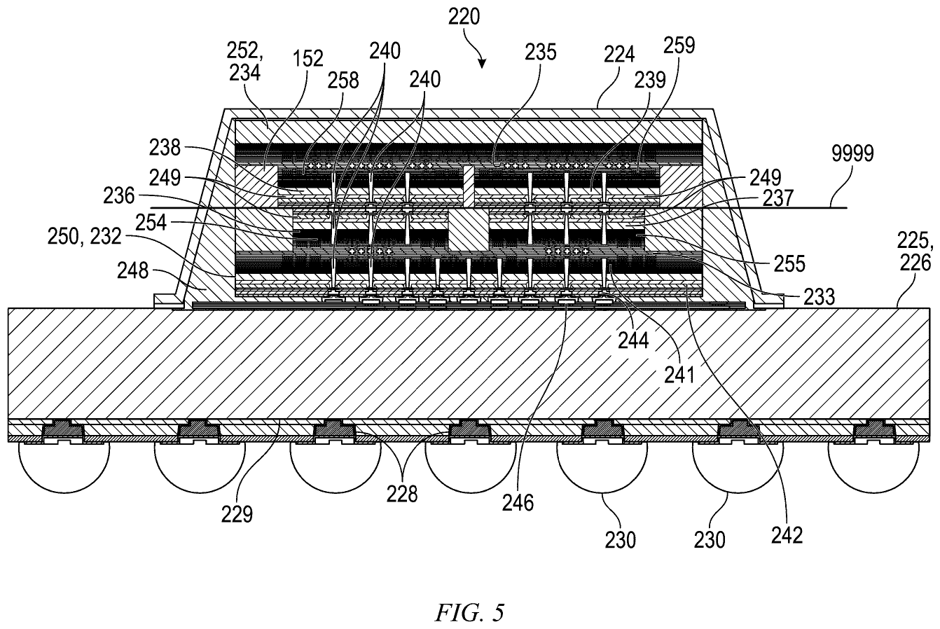

FIG. 5 shows a cross-sectional view of a packaging assembly 220 including a multidie semiconductor structure encapsulated in a package 224 and mounted on an upper surface 225 of substrate, interposer, or printed circuit board 226 and having metal pads 228 and C4 solder bumps 230 attached to metal pads 228 on a lower surface 229. The multidie semiconductor structure includes wafers or dies 232 and 234 and dies 236, 237, 238 and 239 as shown in FIG. 5. Dies 236 and 237 are hybrid bonded to the front side or major surface 233 of wafer 232. Wafer 232 and dies 236 and 237 includes a die to wafer (D2W) structure 250 and can be preassembled. Dies 236 and 237 have TSVs 240 from the front side or major surface or from BEOLs 254 and 255 to the backside of dies 236 and 237 respectively. Wafer 232 has TSVs 240 from the front side or major surface 233 or from the BEOL wiring layer 241 to the backside or lower side 242 of wafer 232 and coupled to metal pads 244 which are coupled through package 224 to metal pads 246 on upper surface 225 of substrate 226.

Dies 238 and 239 are hybrid bonded via metal pads to the front side or major surface 235 of wafer 234. Wafer 234 and dies 238 and 239 include a die to wafer (D2W) structure 252 and can be preassembled. Dies 238 and 239 have TSVs 240 from the front side or major surface or from BEOL 258 and 259 to the backside or lower side of dies 238 and 239 respectively.

Dies 236 to 239 can have a redistribution layer 249 formed on the backside and have metal pads for hybrid bonding. Die to wafer structures 250 and 252 can be hybrid bonded together via metal pads on a redistribution layer 249 or on metal pads on the backside of dies 236, 237, 238 and 239. As shown in FIG. 5, the backside of respective dies 236 and 237 of die to wafer structure 250 are bonded to the backside of respective dies 238 and 239 of die to wafer structure 252. Bonding die to wafer structures 250 and 252 together is characterized in the art as a wafer to wafer (W2W) structure.

FIG. 5 thus depicts, in part, two die-to-wafer (D2W) builds joined together by a wafer-to-wafer (W2W) hybrid bond along line 9999. The upper D2W build is essentially similar to FIG. 3 without solder bumps 162. Package 224 can be encapsulated with an organic or suitable material 248 to provide robust mechanical stability.

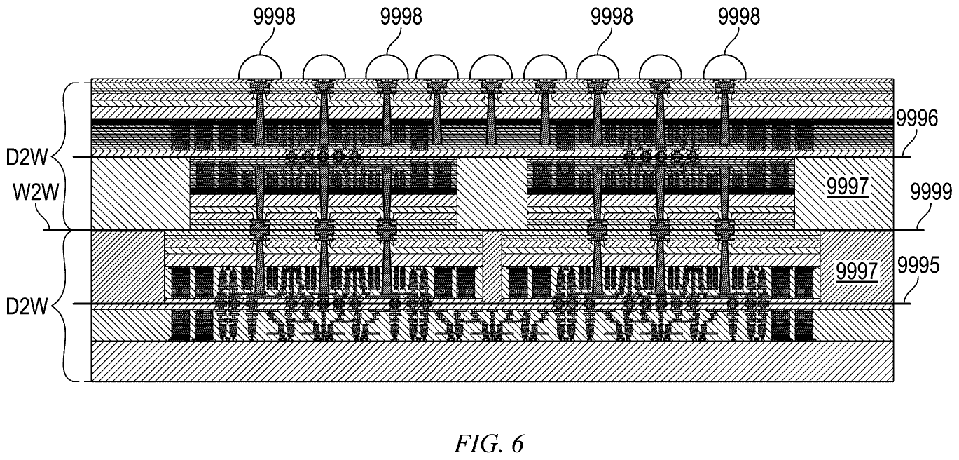

FIG. 6 provides an enlarged view of the two die-to-wafer (D2W) builds joined together by the wafer-to-wafer (W2W) hybrid bond along line 9999. The view is inverted with respect to FIG. 5 and shows solder bumps 9998. Note the encapsulating material 9997. Note also the D2W hybrid bond lines 9996, 9995.

One or more embodiments thus provide multidie semiconductor structures alone or in combination with semiconductor wafers utilizing hybrid bonding and further provides reconstituted semiconductor wafers using hybrid bonding and a thick encapsulating material.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1(SC1 ) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1st Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of the disclosed multidie and wafer semiconductor structures.

An integrated circuit in accordance with aspects of the present inventions can be employed in essentially any application and/or electronic system where one or more aspects of the disclosed multidie and wafer semiconductor structures would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a semiconductor wafer having an insulating surface and a plurality of metal pads thereon; and
a plurality of individual semiconductor dies having a front side and a back side, each die having an insulating surface and metal pads on the front side;
wherein the plurality of individual semiconductor dies are positioned over and hybrid bonded to the semiconductor wafer and wherein respective metal pads and insulating surfaces of the semiconductor wafer and the plurality of semiconductor dies are aligned and hybrid bonded face to face, and
wherein an encapsulating material is positioned over the semiconductor wafer and the plurality of semiconductor dies to provide mechanical stability and an insulating surface over the plurality of individual semiconductor dies.

2. The semiconductor structure of claim 1, wherein the encapsulating material includes an oxide.

3. The semiconductor structure of claim 1 wherein the encapsulating material includes an oxide having a thickness in the range from 10 to 50 micrometers.

4. The semiconductor structure of claim 1 wherein the encapsulating material includes an overmold having an insulating surface.

5. The semiconductor structure of claim 4, wherein the encapsulating material has an insulating surface and has metal pads on the insulating surface suitable for hybrid bonding.

6. The semiconductor structure of claim 5, wherein at least one of the metal pads on the encapsulating material insulating surface is coupled to a metal pad on the backside of one of the individual semiconductor dies.

7. The semiconductor structure of claim 1, wherein at least one of the individual dies has an insulating surface and metal pads on its backside.

8. A semiconductor build comprising:
first and second semiconductor structures, each of the first and second semiconductor structures comprising:
a semiconductor wafer having an insulating surface and a plurality of metal pads thereon; and
a plurality of individual semiconductor dies having a front side and a back side, each die having an insulating surface and metal pads on a front side;
wherein the plurality of individual semiconductor dies are positioned over and hybrid bonded to the semiconductor wafer, wherein respective metal pads and insulating surfaces of the semiconductor wafer and the plurality of dies are aligned and hybrid bonded face to face; and
wherein an encapsulating material is positioned over the semiconductor wafer and the plurality of semiconductor dies to provide mechanical stability and an insulating surface over the plurality of individual semiconductor dies, the overmold insulating surface having metal pads suitable for hybrid bonding, and
wherein the second semiconductor structure is positioned over the first semiconductor structure and wherein the metal pads on the overmold insulating surface of the second semiconductor structure are aligned and hybrid bonded to the metal pads on the overmold insulating surface of the first semiconductor structure.

9. The semiconductor build of claim 8, wherein the first semiconductor structure has at least one of the metal pads on the encapsulating material surface coupled to a metal pad on the backside of one of the individual semiconductor dies.

10. The semiconductor build of claim 8, wherein the encapsulating material includes an oxide having a thickness in the range from 10 to 50 micrometers.

11. The semiconductor build of claim 8, wherein the encapsulating material includes an overmold.

12. A multidie semiconductor structure comprising:
a first die having a semiconductor substrate, semiconductor devices, a back end of the line (BEOL) wiring layer connected to the devices and to metal pads suitable for hybrid bonding on a first major surface of the first die;
a second and third die each having a semiconductor substrate, semiconductor devices, a BEOL wiring layer connected to the devices and to metal pads suitable for hybrid bonding on a first major surface of the second and third die;
each the second and third die further including a plurality of through silicon vias (TSVs) extending from the BEOL wiring layer through the semiconductor substrates to a backside of the second and third die;
the metal pads on the first major surface of the second and third die hybrid bonded to the metal pads on the first major surface of the first die;
an overmold positioned over the first, second and third die to provide added mechanical stability to the first, second and third die; and
a patterned redistribution layer on the overmold and on the backside of the second and third die for forming interconnections to the TSVs, the TSVs coupled to metal pads formed on the patterned redistribution layer.

13. The multidie semiconductor structure of claim 12, wherein the TSVs coupled to the metal pads on the patterned redistribution layer are bonded to metal pads on an interposer.

14. The multidie semiconductor structure of claim 12 wherein the encapsulating material includes an oxide having a thickness in the range from 10 to 50 micrometers.

15. The multidie semiconductor structure of claim 12 wherein the encapsulating material includes an overmold.

16. The multidie semiconductor structure of claim 12, wherein the multidie semiconductor structure is encapsulated on the interposer.

17. The multidie semiconductor structure of claim 12, further including:
a fourth die having a semiconductor substrate, semiconductor devices, a BEOL wiring layer connected to the devices and to metal pads suitable for hybrid bonding on a first major surface of the fourth die; the fourth die further including a plurality of through silicon vias (TSVs) extending from the BEOL wiring layer through the semiconductor substrate to a backside of the fourth die; and
a patterned redistribution layer on the backside of the fourth die for forming interconnections to the TSVs, the TSVs of the fourth die coupled to metal pads formed on the patterned redistribution layer and to corresponding aligned metal pads coupled to TSVs of the second die.

18. The multidie semiconductor structure of claim 17, further including:
a fifth die having a semiconductor substrate, semiconductor devices, and a BEOL wiring layer connected to the devices and to metal pads suitable for hybrid bonding on a first major surface of the fifth die, the fifth die further including a plurality of through silicon vias (TSVs) extending from the BEOL wiring layer through the semiconductor substrate to a backside of the fifth die, the metal pads on the first major surface of the fifth die bring hybrid bonded to the metal pads on the first major surface of the fourth die;
an overmold positioned around the first, fourth and fifth die to provide added mechanical stability to the first, fourth and fifth die; and
a patterned redistribution layer on the backside of the fifth die for forming interconnections to the TSVs, the TSVs of the fifth die coupled to metal pads formed on the patterned redistribution layer.

19. The multidie semiconductor structure of claim 18, further including:
a sixth die having a semiconductor substrate, semiconductor devices, and a BEOL wiring layer connected to the devices and to metal pads suitable for hybrid bonding on a first major surface of the sixth die, the sixth die further including a plurality of through silicon vias (TSVs) extending from the BEOL wiring layer through the semiconductor substrate to a backside of the sixth die; and
a patterned redistribution layer on the backside of the sixth die for forming interconnections to the TSVs, the TSVs of the sixth die coupled to metal pads formed on the patterned redistribution layer and to corresponding aligned metal pads coupled to TSVs of the third die.

20. The multidie semiconductor structure of claim 19, further including:
a seventh die having a semiconductor substrate, semiconductor devices, and a BEOL wiring layer connected to the devices and to metal pads suitable for hybrid bonding on a first major surface of the seventh die, the seventh die further including a plurality of through silicon vias (TSVs) extending from the BEOL wiring layer through the semiconductor substrate to a backside of the seventh die, the metal pads on the first major surface of the fifth die hybrid bonded to the metal pads on the first major surface of the fifth die;
an overmold positioned around the sixth and seventh die to provide added mechanical stability to the sixth and seventh die; and
a patterned redistribution layer on the backside of the seventh die for forming interconnections to the TSVs, the TSVs of the seventh die coupled to metal pads formed on the patterned redistribution layer.
